(19) United States
(12) Patent Application Publication
(10) Pub. No.: US 2026/0239656 A1
(43) Pub. Date: Aug. 13, 2026

(54) VERTICAL GAN MOSHEMTS WITH IMPROVED PERFORMANCE STRUCTURES

(71) Applicants: Nami MOS CO., LTD., New Taipei City (TW); MOSEL VITELIC INC., Hsinchu (TW)

(72) Inventors: Fu-Yuan HSIEH, New Taipei City (TW); Lin XU, Shanghai (CN)

(21) Appl. No.: 19/051,604

(22) Filed: Feb. 12, 2025

(51) Int. Cl. H10D 30/47; H10D 62/10; H10D 62/824; H10D 62/85; H10D 62/852; H10D 84/80

(52) U.S. Cl. CPC H10D 30/477; H10D 62/107; H10D 84/811; H10D 62/824; H10D 62/8503; H10D 62/852

(57) ABSTRACT

An integrated circuit comprising a vertical GaN MOSHEMT and a GaN super barrier rectifier (SBR) electrodes disposed in a gate trench of an unit cell. A first channel region of the GaN HEMT is formed along a first sidewall of the gate trench while a second channel region of the GaN SBR is formed along a first portion of a second sidewall opposite to the first sidewall of the gate trench. A source metal connects with the heterojunctions, body regions of the GaN HEMT and GaN SBR, and the gate electrode of the GaN SBR through a source contact trench, and further connects with a P-shield (PS) region below the gate trench through a grounded P (GP) region along a second portion of the second sidewall of the gate trench.

### FIELD OF THE INVENTION

This invention relates generally to nitride semiconductor devices with improved performance structures, and more particularly, to a gallium nitride (GaN) metal-oxide-semiconductor high electron mobility transistor (MOSHEMT) having an embedded Super barrier rectifier (SBR) in a gate trench of a unit cell to inactivate a parasitic body diode for turn-off switching loss reduction without lowering the channel density of the GaN MOSHEMT.

### BACKGROUND OF THE INVENTION

The heterojunction creates a two-dimensional electron gas (2DEG) with a higher mobility to achieve a lower specific on-resistance than Silicon and Silicon Carbide (SiC). When used as switching devices in converters or inverters, Vertical AlGaN/GaN MOSHEMTs have a parasitic PN diode inside the devices, and the power loss during the reverse conduction mode is large due to a large reverse turn-on voltage characteristic. Therefore, it is common to externally add a freewheeling diode in parallel to reduce the switching loss. However, the addition of the freewheeling diode will increase cost and parasitic inductance.

Moreover, a short circuit (SC) failure is still the most serious reliable issue for GaN devices due to their much smaller device areas compared with Si-MOSFETs resulting in a higher junction temperature before the failure. During the SC transient process, the high direct current (DC) voltage and the large saturation current would be applied to the device, resulting in the devices' performance degradation or even severe burnout failure if the devices do not have sufficient SC withstand capabilities.

Therefore, there is still a need in the art of GaN MOSHEMTs design and fabrication to provide a novel cell structure, device configuration and manufacturing process that would make the Vertical GaN MOSHEMTs have a lower electric-field strength at the gate oxide, achieve a lower specific on-resistance and have a lower saturation current for the SC capability improvement.

### SUMMARY OF THE INVENTION

A nitride semiconductor device comprising at least three epitaxial layers including a top epitaxial layer, a middle epitaxial layer and a bottom epitaxial layer grown on a substrate; the top epitaxial layer having a band gap higher or lower than that of the middle epitaxial layer; a heterojunction is formed at an interface between the top and the middle epitaxial layers; a body region formed at a top portion of the bottom epitaxial layer. A gate trench penetrating through the top and middle epitaxial layers and the body regions, and stopping in the bottom epitaxial layer. A source contact trench penetrating through the top and middle epitaxial layers and body contact regions, and stopping in the bottom epitaxial layer. A metal contact plug filling into the source contact trench and connecting the heterojunction and the body region with a source metal. When the device is turned on, a drain-source current flows from a backside metal as a drain metal to a front metal as a source metal through a drift region in the bottom epitaxial layer, a channel region in the body region along sidewalls of the gate trench, the heterojunction and the metal contact plug in the source contact trench.

The nitride semiconductor device further comprising at least a pair of P-shield (PS) regions of a second conductivity type surrounding bottom regions of the source contact trenches and connecting with the body contact regions. At least one Junction Field Effect Transistor (JFET) region of a first conductivity type sandwiched between the pair of PS regions with a doping concentration higher than that of the bottom epitaxial layer, thus limiting the saturation current in a forward conduction stage for the SC capability improvement. The gate oxide electric field strength is also reduced by the existence of the pair of PS regions as a high electric field is shifted from a channel region to the pair of PS regions.

The invention features a nitride semiconductor further comprising the gate trench having at least a one-step gate trench structure including a first type gate trench and a second type gate trench; the first type gate trench is above the second type gate trench and has a trench width wider than that of the second type gate trench; the first gate electrode disposed in the first gate trench surrounded with a first insulating film on a bottom of the first type gate trench, and with a first gate oxide on gate trench sidewalls of the first type gate trench; the first insulating film having a thickness greater than that of the first gate oxide; a P-Shield (PS) region of a second conductivity type surrounding the second type gate trench filled up with the first insulating film; and at least one grounded P (GP) region of a second conductivity type surrounding a sidewall of the first type gate trench connecting with a body region and the PS region.

The present invention also discloses an integrated circuit comprising a vertical GaN MOSHEMT and a GaN super barrier rectifier (SBR) with two gate electrodes disposed in a gate trench of a unit cell side by side. A first channel region of the GaN MOSHEMT is formed along a first sidewall of the gate trench while a second channel region of the GaN SBR is formed along a first portion of a second sidewall opposite to the first sidewall of the gate trench. A source metal connects with the heterojunctions, the body regions of the GaN MOSHEMT and the GaN SBR, and the gate electrode of the GaN SBR through a contact metal plugs filling into a source contact trench, and further connects with a P-shield (PS) region below the gate trench through a grounded P (GP) region along a second portion of the second sidewall of the gate trench.

According to another aspect, an integrated circuit comprising a first gate electrode of the GaN MOSHEMT disposed in an upper portion of a gate trench, and a shielded gate electrode grounded to a source metal as a second gate electrode of the GaN SBR disposed below the first gate electrode and isolated from the first gate electrode by an inter-poly oxide (IPO) layer; the first gate electrode laterally isolated from epitaxial layers by a first gate oxide of the GaN MOSHEMT on sidewalls of the gate trench, and the shielded gate electrode vertically isolated from the epitaxial layers with a second gate oxide of the GaN SBR on a bottom region of the gate trench, wherein the second gate oxide has a thickness less than that of the first gate oxide; a first channel region of the GaN MOSHEMT formed along a first sidewall, while a second channel region of the GaN SBR formed along the bottom region of the gate trench.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a cross-sectional view showing a preferred nitride semiconductor device embodiment comprising three epitaxial layers including a top epitaxial layer, a middle epitaxial layer and a bottom epitaxial layer according to the present invention.

FIG. 1B is a cross-sectional view showing another preferred nitride semiconductor device embodiment comprising three epitaxial layers including a top epitaxial layer, a middle epitaxial layer and a bottom epitaxial layer wherein the materials of the top and the middle epitaxial layers are interchanged according to the present invention.

FIG. 1C is a cross-sectional view showing another preferred nitride semiconductor device embodiment comprising three epitaxial layers wherein the gate oxide is an atomic layer deposited SiO₂, Al₂O₃ or HfO₂ layer padded with an Aluminum Nitride (AlN) or unintentionally doped (UID) GaN interlayer on sidewalls of the gate trench for channel mobility enhancement according to the present invention.

FIG. 1D is a cross-sectional view showing another preferred nitride semiconductor device embodiment comprising three epitaxial layers with an N type source region disposed on a top portion of the top epitaxial layer according to the present invention.

FIG. 2 is a cross-sectional view showing another preferred nitride semiconductor device embodiment comprising three epitaxial layers with two heterojunctions formed above the body regions according to the present invention.

FIG. 3 is a cross-sectional view showing another preferred nitride semiconductor device embodiment comprising three epitaxial layers wherein doping concentration variations of the PS1 regions (from PS1t region to PS1b region) and the N type regions (from JFET1t region to N+ substrate) are depicted separately along the vertical direction according to the present invention.

FIG. 4 is a cross-sectional view showing another preferred nitride semiconductor device embodiment comprising three epitaxial layers with a shielded gate electrode disposed below a gate electrode in the gate trench according to the present invention.

FIG. 5 is a cross-sectional view showing another preferred nitride semiconductor device embodiment comprising three epitaxial layers with an additional N buffer layer sandwiched between the N+ substrate and the PC regions, and a Junction Field Effect Transistor (JFET) region formed between the two adjacent SPS regions according to the present invention.

FIG. 6A is a cross-sectional view showing another preferred nitride semiconductor device embodiment representing an IGBT with a P+ substrate according to the present invention.

FIG. 6B is a cross-sectional view showing another preferred nitride semiconductor device embodiment representing an IGBT with a plurality of alternating P+ and N+ regions in the P+ substrate according to the present invention.

FIG. 7 is a cross-sectional view showing another preferred nitride semiconductor device embodiment comprising three epitaxial layers with a L-Shape P-shield (LPS) region beneath the gate trench, and aside a sidewall of the gate trench and adjoining a lower surface of the body region according to the present invention.

FIG. 8 is a cross-sectional view showing another preferred nitride semiconductor device embodiment comprising three epitaxial layers with a one-step gate trench structure and an additional second P-shield (PS2) region of a second conductivity type according to the present invention.

FIG. 9A a cross-sectional view showing another preferred nitride semiconductor device embodiment comprising three epitaxial layers with two gate electrodes disposed in the gate trench side by side according to the present invention.

FIG. 9B a cross-sectional view showing another preferred nitride semiconductor device embodiment comprising three epitaxial layers with two gate electrodes disposed in the gate trench side by side and an N type source region disposed on a top portion of the top epitaxial layer according to the present invention.

FIG. 10A is a top view of a preferred embodiment for a trench semiconductor power device with stripe cells layout according to the present invention.

FIG. 10B is a top view of another preferred embodiment for a trench semiconductor power device with stripe cells layout according to the present invention.

FIG. 10C is a cross-sectional view showing a preferred A1-A1′ cross section of FIG. 10A comprising three epitaxial layers with a one-step gate trench structure and an additional second P-shield (PS2) region of a second conductivity type according to the present invention.

FIG. 10D is a cross-sectional view showing a preferred B1-B1′ cross section of FIG. 10A comprising three epitaxial layers with grounded P (GP) regions formed along a second trench sidewall of the first type gate trench according to the present invention.

FIG. 10E is a cross-sectional view showing a preferred C1-C1′ cross section of FIG. 10A representing the gate electrode contact area of the GaN SBR according to the present invention.

FIG. 10F is a cross-sectional view showing a preferred D1-D1′ cross section of FIG. 10A representing the gate electrode contact area of the GaN MOSFET according to the present invention.

FIG. 10G is a cross-sectional view showing another preferred A1-A1′ cross section of FIG. 10A with an N type source region disposed on a top portion of the top epitaxial layer according to the present invention.

FIG. 11A is a cross-sectional view showing another preferred A1-A1′ cross section of FIG. 10A with a P+ substrate according to the present invention.

FIG. 11B is a cross-sectional view showing another preferred A1-A1′ cross section of FIG. 10A representing an IGBT with a plurality of alternating P+ and N+ regions in the P+ substrate according to the present invention.

FIG. 12A is a top view of a preferred embodiment for a trench semiconductor power device with stripe cells layout according to the present invention.

FIG. 12B is a cross-sectional view showing a preferred A2-A2′ cross section of FIG. 12A with a second p body region and a first N type source region surrounding a second sidewall of the gate trench according to the present invention.

FIG. 12C is a cross-sectional view showing a preferred B2-B2′ cross section of FIG. 12A representing the shielded gate electrode contact area according to the present invention.

FIG. 12D is a cross-sectional view showing a preferred A2-A2′ cross section of FIG. 12A with a second N type source region on a top portion of the top epitaxial layer according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

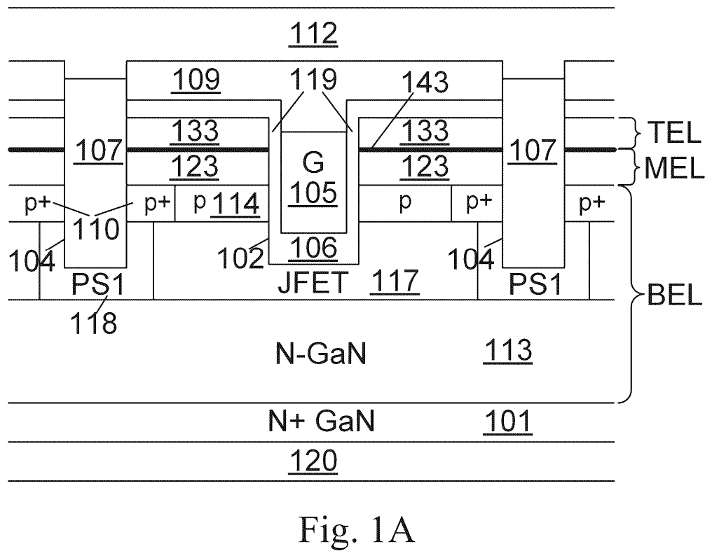

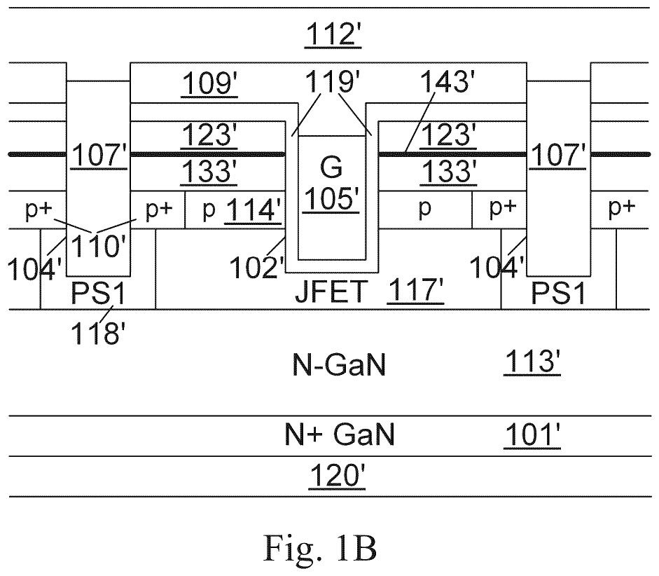

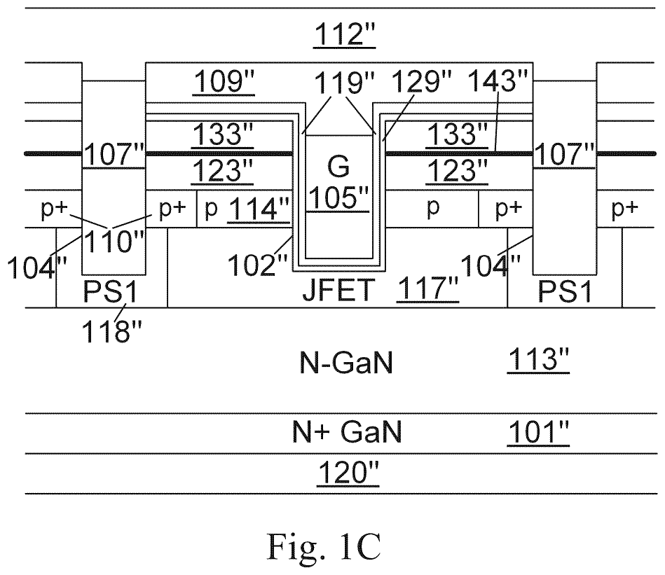

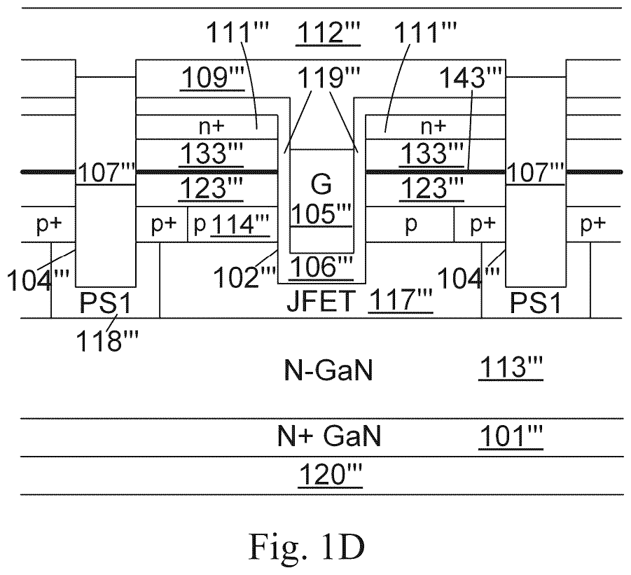

Please refer to FIG. 1A for a preferred embodiment of this invention. The preferred embodiment comprises a nitride semiconductor device formed on an N+type GaN (N+GaN, as illustrated) substrate 101 with a less doped N type GaN (N−GaN, as illustrated) bottom epitaxial layer (BEL, as illustrated) 113 extending thereon, wherein the N+GaN substrate 101 is coated with a back metal 120 on the rear side as a drain metal. A AlGaN layer or a Al_{X}Ga_{Y}N layer wherein 0<X<1 and Y=1−X as the top epitaxial layer (TEL, as illustrated) 133 and an N GaN layer as the middle epitaxial layer (MEL, as illustrated) 123 are formed on the N−GaN bottom epitaxial layer 113, wherein the top epitaxial layer 133 has a band gap higher than that of the middle epitaxial layer 123, and a heterojunction 143 is thus formed at an interface between the top epitaxial layer 133 and the middle epitaxial layer 123. P type GaN (P GaN) body regions 114 are formed at a top portion of the bottom epitaxial layer 113 and connect with the p+body contact region 110 disposed into a top portion of the bottom epitaxial layer 113. Inside the N type epitaxial layer, a plurality of gate trenches 102 and source contact trenches 104 are formed vertically downward from a top surface of the top epitaxial layer 133 and penetrating through the top epitaxial layer 133 and the middle epitaxial layer 123, the p body regions 114, and stopping in the bottom epitaxial layer 113. Inside each of the gate trenches 102, a gate electrode (G, as illustrated) 105 is disposed in an upper portion and laterally isolated from the adjacent epitaxial layer by a first gate oxide (GOX1) 119, and vertically isolated from the adjacent epitaxial layer by a first insulating film 106 on a bottom region of the gate trench 102 with a thickness greater than that of the gate oxide 119, wherein the gate oxide 119 is an atomic layer deposited SiO₂, Al₂O₃ or HfO₂ layer. In the bottom epitaxial layer 113, a pair of first P-shield (PS1, as illustrated) regions 118 of a second conductivity type are formed and separated from each other in a horizontal direction by an N type Junction Field Effect Transistor (JFET, as illustrated) region 117, and a doping concentration of the JFET region 117 is higher than that of the bottom epitaxial layer 113. Each of the one pair of PS1 regions surrounds a bottom region of the source contact trench 104 and connects with the p+ body contact region 110, and a contact metal plug 107 is formed filling into the source contact trench 104 to connect the heterojunction 143 and the p body region 114 with a source metal 112. Moreover, an interlayer dielectric film 109 is stacked on the epitaxial layer, and the source metal 112 is formed onto the interlayer dielectric film 109.

Please refer to FIG. 1B for another preferred embodiment of this invention with a new and improved device structure. The GaN device has a similar structure to FIG. 1A, except that the materials of the top and the middle epitaxial layers are interchanged in the present invention. In the present invention, an N-GaN layer as the top epitaxial layer 123′ and an N type AlGaN (N-AlGaN) layer as the middle epitaxial layer 133′ are formed on the N-GaN bottom epitaxial layer 113′. Moreover, a gate oxide 119′ is deposited on sidewalls and a bottom region of the gate trench 102′.

Please refer to FIG. 1C for another preferred embodiment of this invention with a new and improved device structure. The GaN device has a similar structure to FIG. 1A, except that the gate oxide in the present invention is an atomic layer deposited SiO₂, Al₂O₃ or HfO₂ layer 119″ padded with an Aluminum Nitride (AlN) or unintentionally doped (UID) GaN interlayer 129″ on both sidewalls of the gate trench 102″ for the channel mobility enhancement.

Please refer to FIG. 1D for another preferred embodiment of this invention with a new and improved device structure. The GaN device has a similar structure to FIG. 1A, except that the present invention further comprises an n+ source region 111″ disposed on a top portion of the top epitaxial layer 133″, connecting with the gate trench 102″ and the source contact trench 104″ for on-resistance reduction, wherein the n+ source region 111″ is formed by the deposition of a heavily doped N type nitride semiconductor layer or by Si ion implantation into the top epitaxial layer 133″.

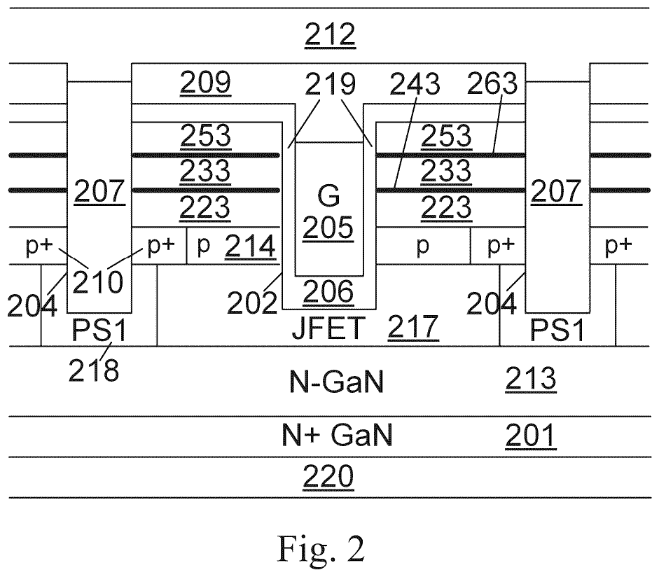

Please refer to FIG. 2 for another preferred embodiment of this invention with a new and improved device structure. The GaN device has a similar structure to FIG. 1A, except that the present invention further comprises three epitaxial layers of Al_{X}Ga_{Y}N/GaN/Al_{X}Ga_{Y}N 253/233/223 on top of the p body region 214, and two heterojunctions 243 and 263 are formed at the two interfaces of the three epitaxial layers above the p body region 214, wherein X=1 and Y=1, or 0<X<1 and Y=1−X.

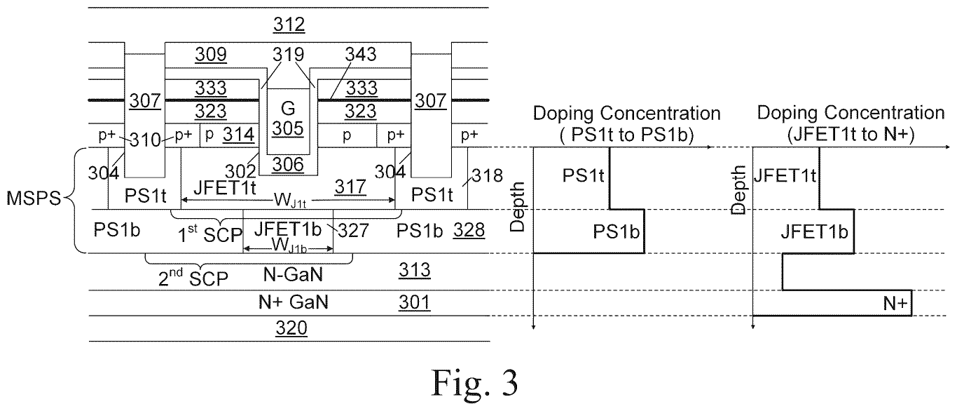

Please refer to FIG. 3 for another preferred embodiment of this invention with a new and improved device structure wherein doping concentration variations of the PS1 regions (from PS1t region to PS1b region) and the N type regions (from JFET1t region to N+ substrate) are depicted separately along the vertical direction. The GaN device has a similar structure to FIG. 1A, except that the present invention comprises multiple stepped P-shield (MSPS, as illustrated) regions in the bottom epitaxial layer 313 including a pair of bottom first P-shield (PS1b, as illustrated) regions 328 with a doping concentration D_{PS1b} and a pair of top first P-shield (PS1t, as illustrated) regions 318 above the PS1b regions 328 with a doping concentration D_{PS1t}, wherein D_{PS1t}<D_{PS1b}, and two first JFET (JFET1) regions are formed including a bottom JFET1 (JFET1b, as illustrated) region 327 with a width W_{J1b} and a doping concentration D_{JFET1b} and a top JFET1 (JFET1t, as illustrated) region 317 above the JFET1b region 327 with a width W_{J1t} and a doping concentration D_{JFET1t}, wherein W_{J1b}<W_{J1t} and D_{JFET1b}>D_{JFET1t}, while D_{JFET1b} is lower than a doping concentration D_{N+} of the N+ GaN substrate 301 and D_{JFET1t} is higher than a doping concentration D_{N} of the N-GaN bottom epitaxial layer 313, the relationships among doping concentrations of the N type regions are D_{N}<DJ_{FET1t}<D_{JFET1b}<D_{N+}. The doping concentration profile of each region of the PS1 (PS1t and PS1b) regions and the JFET1 (JFETt and JFETb) regions is uniform. The JFET1b region 327 and JFET1t region 317 are formed between the pair of PS1b regions 328 and the pair of PS1t regions 318, respectively. Moreover, a first saturation current pinching (1^{st} SCP, as illustrated) structure comprising a JFET1t region 317 sandwiched between the two top PS1t regions 318 and a second saturation current pinching (2^{nd} SCP, as illustrated) structure comprising a JFET1b region 327 sandwiched between the two bottom PS1b regions 328 are formed to clamp the voltage, thus limiting the saturation current in a forward conduction stage for the short-circuit capability improvement.

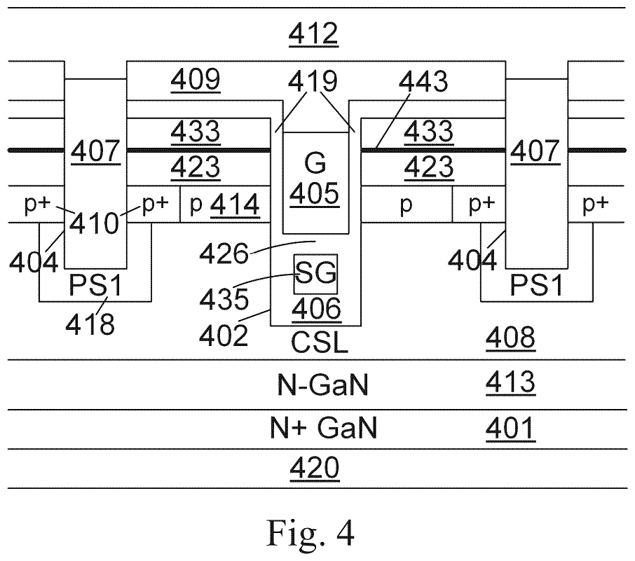

Please refer to FIG. 4 for another preferred embodiment of this invention with a new and improved device structure. The GaN device has a similar structure to FIG. 1A, except that the present invention has a different shielded gate structure in the gate trenches 402 and further comprises an additional N type current spreading layer (CSL, as illustrated) 408 formed at a top portion of the bottom epitaxial layer 413 below the p body regions 414 with a doping concentration higher than that of the bottom epitaxial layer 413. In the present structure, inside each of the gate trenches 402, a shielded gate electrode (SG, as illustrated) 435 is disposed in a lower portion of the gate trench below the gate electrode (G, as illustrated) 405 in an upper portion, and the gate electrode 405 is laterally isolated from the adjacent epitaxial layer with a gate oxide 419 on the gate trench sidewall, the shielded gate electrode 435 is isolated from the adjacent epitaxial layer by an insulating layer 406, wherein the insulating layer 406 has a thicker thickness than the first gate oxide 419. Meanwhile, the shielded gate electrode 435 and the gate electrode 405 is insulated from each other by another insulating film 426 as an inter-poly oxide (IPO) layer.

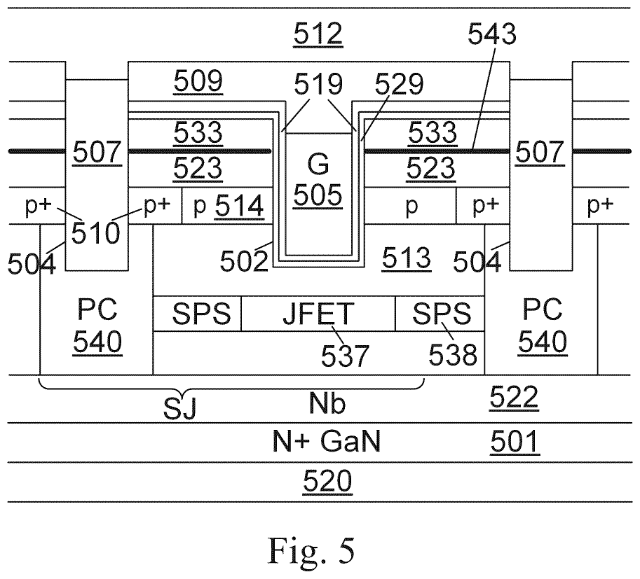

Please refer to FIG. 5 for another preferred embodiment of this invention with a new and improved device structure. The GaN device has a similar structure to FIG. 1C, except that the PS1 regions in FIG. 1C don't exist in the present invention, and the present invention further comprises P column (PC, as illustrated) regions 540 of a second conductivity type formed adjoining bottom surfaces of the p body regions 514 above the N+ substrate 501. A super junction (SJ, as illustrated) structure is thus generated by the N type epitaxial layer 513 and the PC region 540. An additional N buffer layer (Nb, as illustrated) 522 with a resistivity Rb is sandwiched between the N+ substrate 501 and the PC regions 540, wherein Rb is higher than a resistivity R of the bottom N type epitaxial layer 513. Moreover, two sidewall P-shield (SPS, as illustrated) regions 538 of a second conductivity type facing each other are formed horizontally adjoining the PC regions 540 and being spaced apart from the p body regions 514 with a doping concentration higher than that of the PC regions 540, and a Junction Field Effect Transistor (JFET, as illustrated) region 537 of a first conductivity type is formed between the two SPS regions 538 with a doping concentration higher than that of the bottom N type epitaxial layer 513.

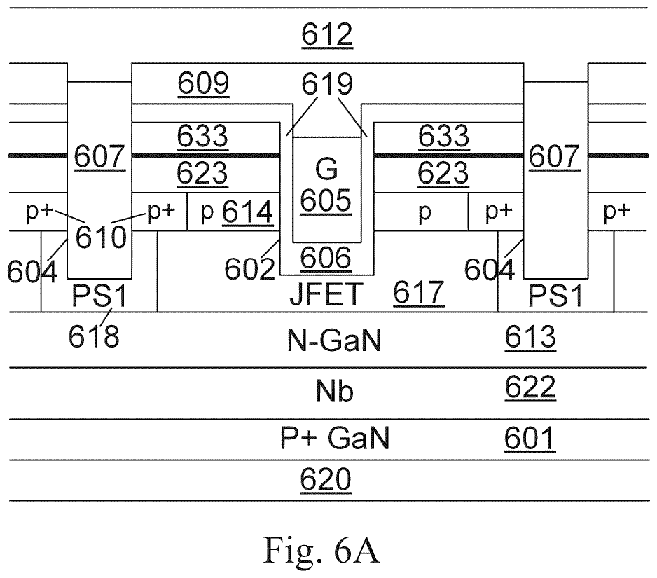

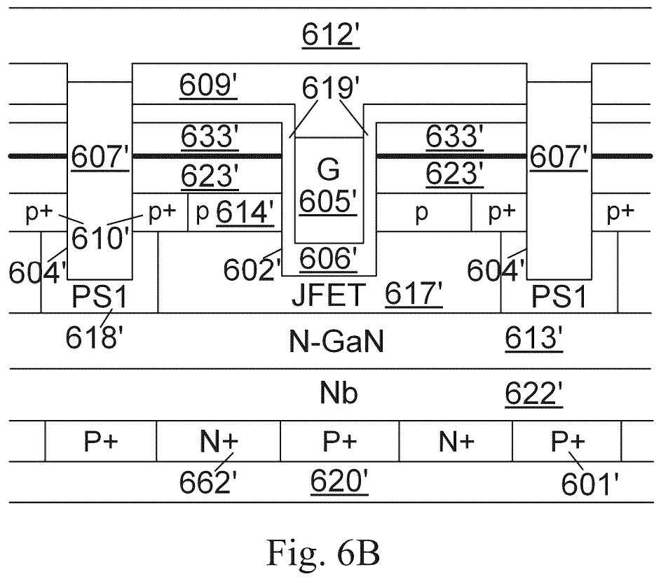

Please refer to FIG. 6A for another preferred embodiment of this invention with a new and improved device structure. The GaN device has a similar structure to FIG. 1A, except for the different substrate and an additional buffer layer. In this invention, the GaN device is formed on a P+GaN substrate 601, and the N−GaN buffer (Nb, as illustrated) layer 622 is sandwiched between the P+GaN substrate 601 and the bottom epitaxial layer 613 with a resistivity Rb lower than a resistivity R of the bottom epitaxial layer 613.

Please refer to FIG. 6B for another preferred embodiment of this invention with a new and improved device structure. The GaN device has a similar structure to FIG. 6A, except that, the GaN device in FIG. 6B further comprises a plurality of heavily doped N+GaN regions 662′ in the P+GaN substrate 601′ to form a plurality of alternating P+ and N+ regions in the substrate.

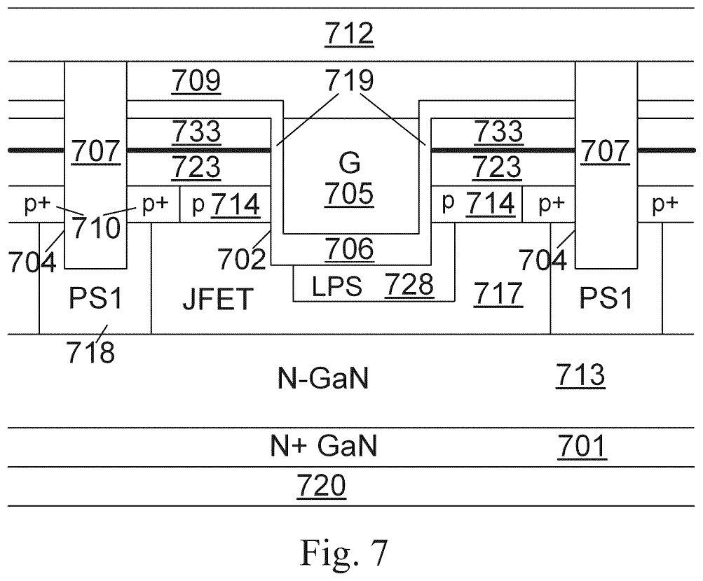

Please refer to FIG. 7 for another preferred embodiment of this invention with a new and improved device structure. The GaN device has a similar structure to FIG. 1A, except that the present invention further comprises a L-Shape P-shield (LPS, as illustrated) region 728 of a second conductivity type beneath the gate trench 702 and aside a sidewall of the gate trench 702 and adjoining a lower surface of the p body region 714.

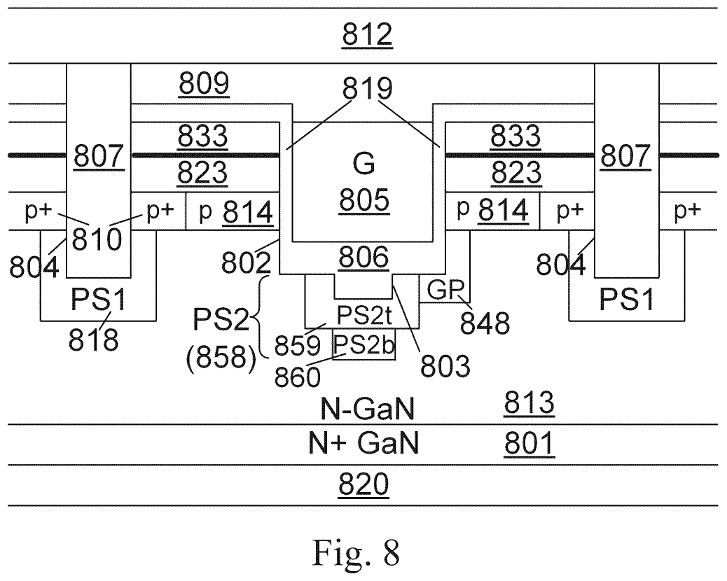

Please refer to FIG. 8 for another preferred embodiment of this invention with a new and improved device structure. The GaN device has a similar structure to FIG. 1A, except that the JFET region in FIG. 1A doesn't exist in the present invention, and the gate trench in the present invention has a one-step gate trench structure comprising a first type gate trench 802 and a second type gate trench 803, wherein the first type gate trench 802 is above the second type gate trench 803 with a gate width greater than that of the second type gate trench 803. A gate electrode (G, as illustrated) 805 is disposed in the first type gate trench 802 surrounded with a thick bottom oxide as the first insulating film 806 on a bottom region of the first type gate trench 802, and surrounded with a gate oxide 819 on sidewalls of the first type gate trench 802, wherein the gate oxide 819 has a less thickness than the first insulating film 806, and the second type gate trench 803 is filled up with the first insulating film 806. The GaN device in FIG. 8 further comprises a second P-shield (PS2, as illustrated) region 858 of a second conductivity type for the gate oxide electric-field reduction surrounding the bottom and sidewalls of the second type gate trench 803. The PS2 region 858 comprises two sub-PS2 regions including a top PS2 (PS2t, as illustrated) region 859 and a bottom PS2 (PS2b, as illustrated) region 860, wherein the PS2b region 860 is below the PS2t region 859 with a doping concentration lower than that of the PS2t region 859. Moreover, a grounded P (GP, as illustrated) region 848 of a second conductivity type is formed surrounding a sidewall of the first type gate trench 802, connecting the PS2 region 858 to the p body region 814.

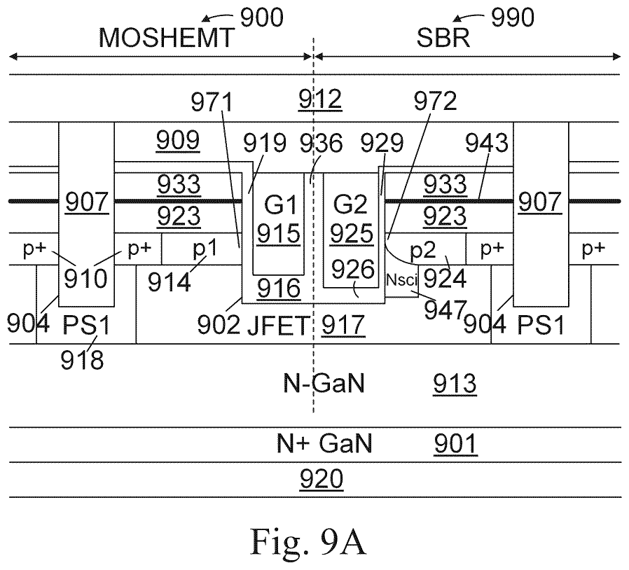

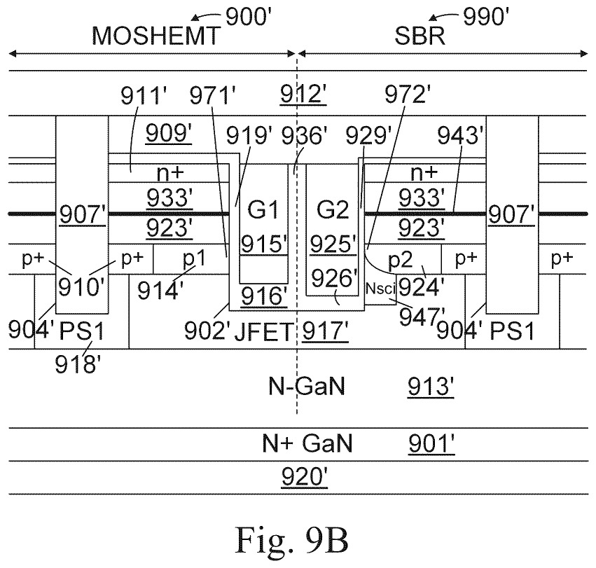

Please refer to FIG. 9A for another preferred embodiment of this invention with a new and improved device structure wherein a GaN MOSHEMT 900 and a GaN SBR 990 are integrated in a single unit cell which is formed on an N+type GaN (N+GaN, as illustrated) substrate 901 with a less doped N type GaN (N−GaN, as illustrated) bottom epitaxial layer 913 extending thereon, wherein the N+GaN substrate 901 is coated with a back metal 920 on the rear side as a drain metal. An N type AlGaN layer as the top epitaxial layer 933 and an N type GaN layer as the middle epitaxial layer 923 are formed on the N-GaN bottom epitaxial layer 913, wherein the top epitaxial layer 933 has a different band gap from that of the middle epitaxial layer 923, and a heterojunction 943 is thus formed at an interface between the top epitaxial layer 933 and the middle epitaxial layer 923. A first p type (p1, as illustrated) body region 914 of the GaN MOSHEMT 900 and a second p type (p2, as illustrated) body region 924 of the GaN SBR 990 are formed at a top portion of the bottom epitaxial layer 913, and connect with the p+ body contact region 910 disposed into a top portion of the bottom epitaxial layer 913. Inside the N type epitaxial layer, a plurality of gate trenches 902 and source contact trenches 904 are formed vertically downward from a top surface of the top epitaxial layer 933 and penetrating through the second epitaxial layer 923, the p1 body regions 914, the p2 body regions 924, the p+ contact regions 910, and stopping in the bottom epitaxial layer 913. Inside each of the gate trenches 902, a first gate electrode (G1, as illustrated) 915 of the GaN MOSHEMT 900 and a second gate electrode (G2, as illustrated) 925 of the SiC SBR 990 are formed side by side. The first gate electrode 915 is laterally isolated from the adjacent epitaxial layer by a first gate oxide (GOX1) 919 of the GaN MOSHEMT 900 on the first gate trench sidewall, and vertically isolated from the adjacent epitaxial layer by a first insulating film 916 on a bottom region of the gate trench 902 with a thickness greater than that of the first gate oxide 919. The second gate electrode 925 is vertically isolated from the adjacent epitaxial layer by a second insulating film 926 of the GaN SBR 990 on a bottom of the gate trench 902, and laterally isolated from the first gate electrode 915 and the adjacent epitaxial layer by an inter-polysilicon oxide (IPO) 936 and a second gate oxide (GOX2) 929 of the GaN SBR 990 on the second gate trench sidewall, respectively, wherein the second gate oxide (GOX2) 929 has a thickness thinner than that of the first gate oxide (GOX1) 919 and the second insulating film 926, and the second gate trench sidewall is opposite to the first gate trench sidewall. A GaN MOSHEMT channel region 971 as a first channel region is formed in the p1 body region 914 along a first sidewall of the gate trench 902, and a GaN SBR channel region 972 as a second channel region is formed in the p2 body region 924 along a second sidewall of the gate trench 902 opposite to the first sidewall, wherein the second channel region 972 has a channel length shorter than that of the first channel region 971. In t he GaN SBR 990, an N type short channel implant (Nsci, as illustrated) region 947 is formed along a second sidewall of the gate trench 902 and surrounding the second gate electrode 925 with a doping concentration higher than that of the bottom epitaxial layer 913, and the second gate electrode 925 is shorted to the source metal 912. In the bottom epitaxial layer 913, a pair of first P-shield (PS1, as illustrated) regions 918 of a second conductivity type are formed and separated from each other in a horizontal direction by an N type Junction Field Effect Transistor (JFET, as illustrated) region 917, and a doping concentration of the JFET region 917 is higher than that of the bottom epitaxial layer 913. Each of the one pair of PS1 regions 917 surrounds a bottom region of the source contact trench 904 and connects with the p+ body contact region 910, and a contact metal plug 907 is formed filling into the source contact trench 904 to connect the heterojunction 943 and the p body region 910 with a source metal 912. Moreover, an interlayer dielectric film 909 is stacked on the epitaxial layer, and the source metal 912 is formed onto the interlayer dielectric film 909.

Please refer to FIG. 9B for another preferred embodiment of this invention with a new and improved device structure. The GaN device has a similar structure to FIG. 9A, except that the present invention further comprises an n+ source region 911′ disposed on a top portion of the top epitaxial layer 933′, connecting with the gate trench 902′ and the source contact trench 904′ for on-resistance reduction, wherein the n+ source region 911′ is formed by the deposition of a heavily doped N type nitride semiconductor layer or by Si ion implantation into the top epitaxial layer 933′.

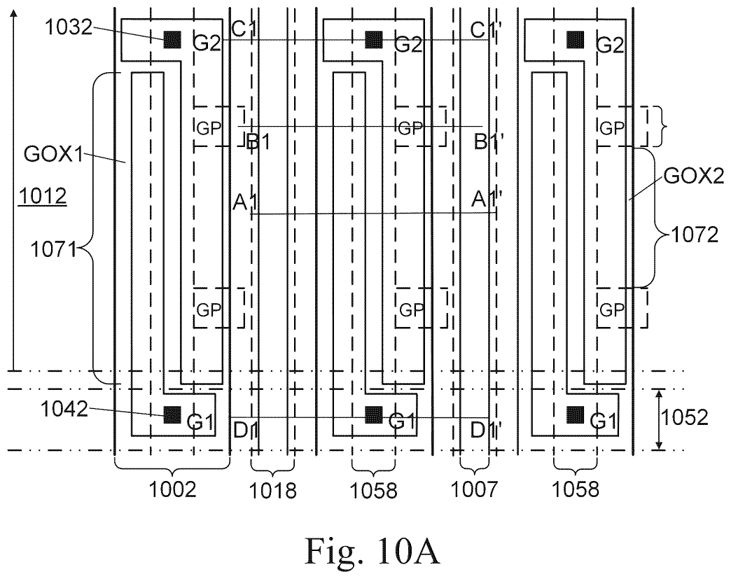

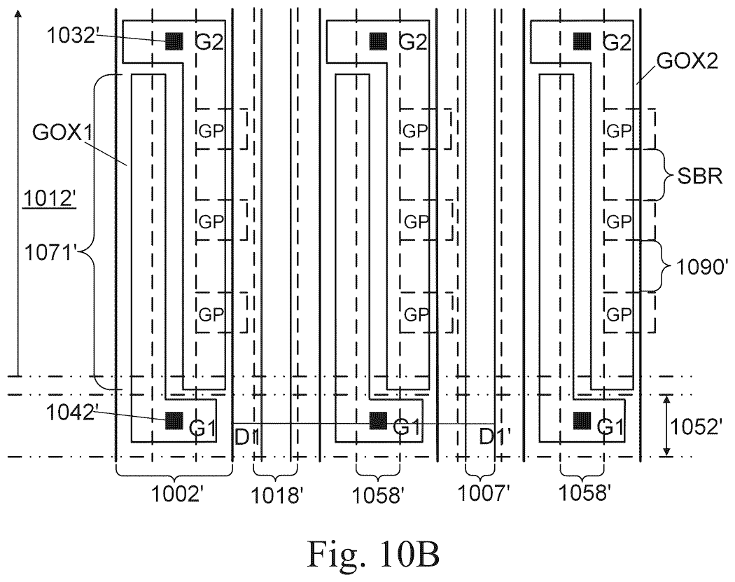

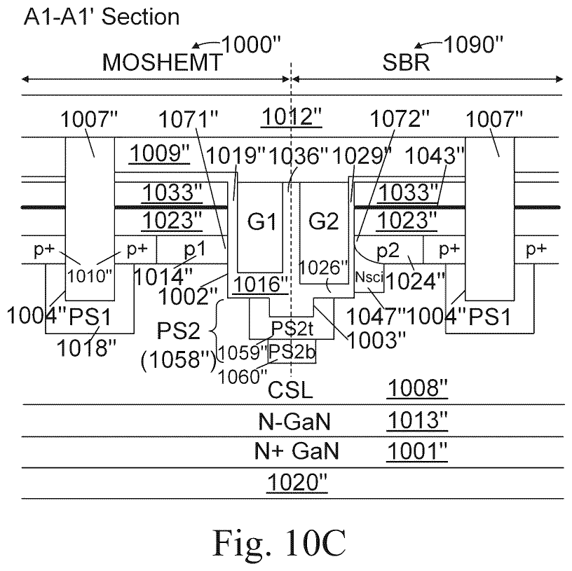

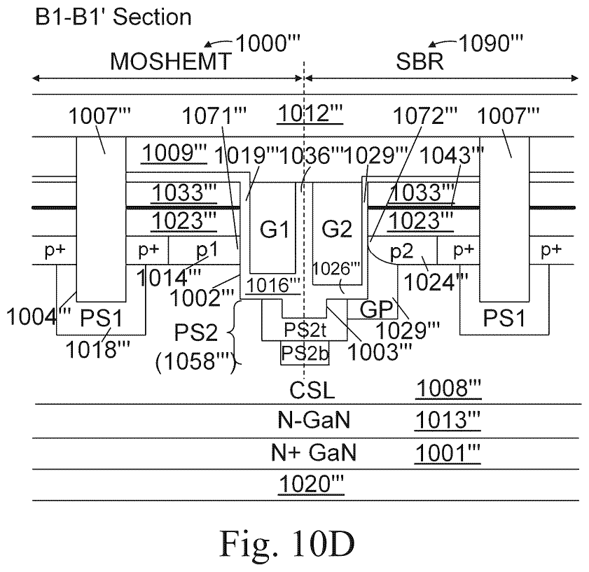

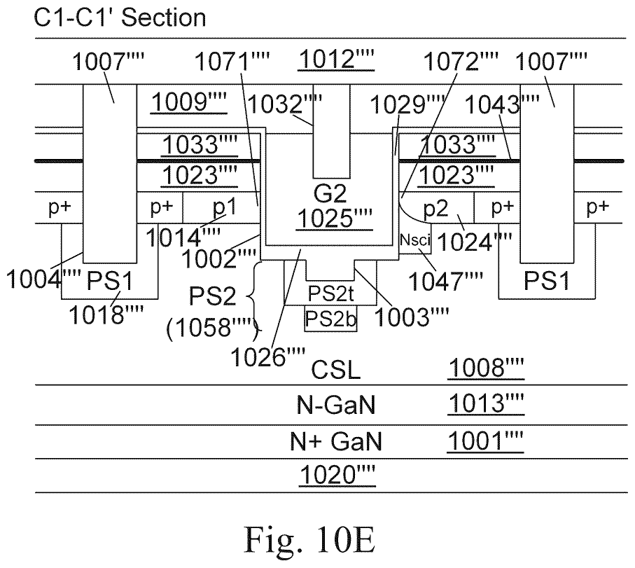

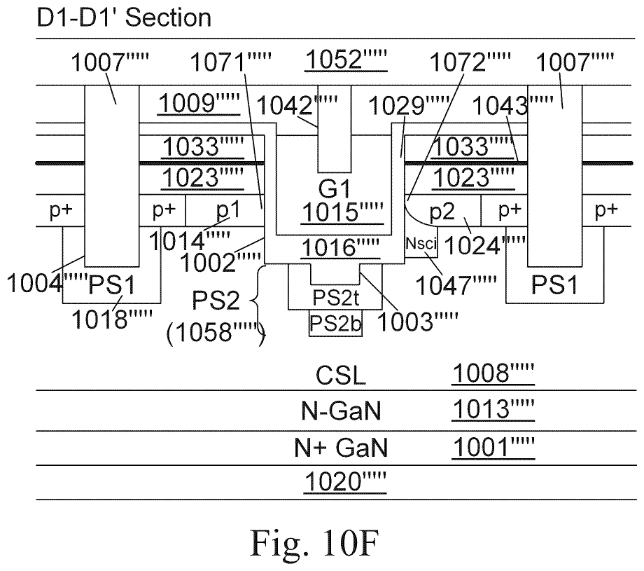

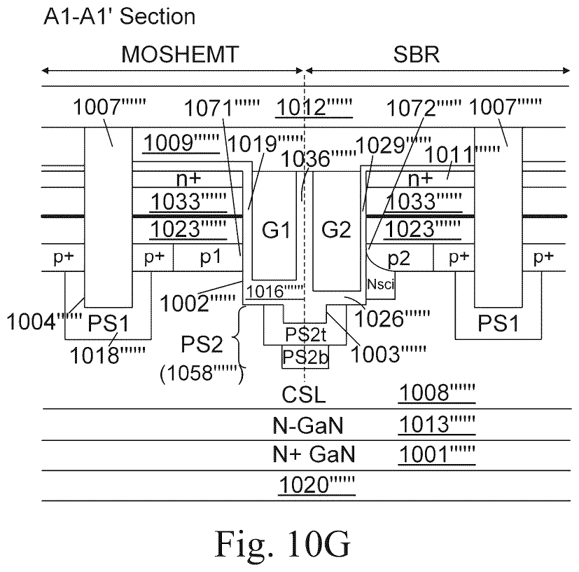

Please refer to FIG. 10A for a top view of a GaN power device having an asymmetric gate trench structure with stripe cells layout. A stripe gate trench 1002 surrounds a second P-shield (PS2) region 1058 in each unit cell, and trenched source contacts 1007 are disposed between the adjacent gate trenches 1002. Moreover, the PS2 regions 1058 are grounded to a source metal 1012 through the grounded P (GP, as illustrated) regions and the trenched source contacts 1007, while the trenched source contacts 1007 are surrounded by the first PS (PS1) regions 1018. According to this invention, a MOSFET channel region 1071 is formed along a first sidewall of the gate trench 1002 with a gate oxide GOX1 and a SBR channel region 1072 is formed along a second sidewall of the gate trench 1002 between the two GP regions with a gate oxide GOX2, wherein GOX1 has a thickness thicker than that of GOX2. Two gate electrodes are formed in the gate trench 1002, wherein the first gate electrode is shorted to a gate metal runner 1052 through a gate contact (G1, as illustrated) 1042 of the GaN MOSHEMT and the second gate electrode is shorted to a source metal 1012 through a gate contact (G2, as illustrated) 1032 of the GaN SBR.

Please refer to FIG. 10B for another top view of a GaN power device having an asymmetric gate trench structure with stripe cells layout. The GaN power device has a similar structure to FIG. 10A, except that in the present invention, the GP regions and the SBR regions 1090′ are alternately formed along the second trench sidewall of the gate trench 1002′.

Please refer to FIG. 10C for a preferred embodiment of A1-A1′ cross-sectional view of FIG. 10A with a new and improved device structure. The GaN device has a similar structure to FIG. 9A, except that the JFET region in FIG. 9A doesn't exist in the present invention, and the gate trench in the present invention has a one-step gate trench structure comprising a first type gate trench 1002″ and a second type gate trench 1003″, wherein the first type gate trench 1002″ is above the second type gate trench 1003″ with a gate width greater than that of the second type gate trench 1003″, and the second type gate trench 1003″ is filled up with the first insulating film 1016″. The GaN device in FIG. 10A further comprises a second P-shield (PS2, as illustrated) region 1058″ of a second conductivity type for the gate oxide electric-field reduction surrounding the bottom and sidewalls of the second type gate trench 1003″ filled up with the first insulating film 1016″. The PS2 region 1058″ comprises two sub-PS2 regions including a top PS2 (PS2t, as illustrated) region 1059″ and a bottom PS2 (PS2b, as illustrated) region 1060″, wherein the PS2b region 1060″ is below the PS2t region 1059″ with a doping concentration lower than that of the PS2t region 1059″.

Please refer to FIG. 10D for a preferred embodiment of B1-B1′ cross-sectional view of FIG. 10A with a new and improved device structure. The GaN power device has a similar structure to FIG. 10C, except that the short channel implant (Nsci, as illustrated) region don't exist in the present invention, and the invention in FIG. 10D further comprises a grounded P (GP, as illustrated) region 1029′″ formed along a second portion of the second trench sidewall of the first type gate trench 1002′″ to ground the PS2 region 1058′″ to a source metal 1012′″ through the p2 body region 1024′″ and the source contact 1007′″ for the gate oxide electric field reduction.

Please refer to FIG. 10E for a preferred embodiment of C1-C1′ cross-sectional view of FIG. 10A, which is a cross-sectional view of the gate electrode contact area of the GaN SBR. In the present invention, a second gate electrode (G2, as illustrated) 1025″″ is formed in an upper portion of each of the first type gate trenches 1002″″, and the second gate electrode 1025″″ is isolated from the N type epitaxial layer by a second gate oxide film (GOX2) 1029″″ along trench sidewalls and a second insulating film 1026″″ on a bottom of the gate trench, wherein the second gate oxide film 1029″″ has a thinner thickness than that of the second insulating film 1026″″, and furthermore, the second gate electrode 1025″″ is connected to a source metal 1012″″ through a trenched contact 1032″″.

Please refer to FIG. 10F for a preferred embodiment of D1-D1′ cross-sectional view of FIG. 10A, which is a cross-sectional view of the gate electrode contact area of the GaN MOSHEMT. In the present invention, a first gate electrode (G1, as illustrated) 1015′″″ is formed in an upper portion of each of the first type gate trenches 1002′″″, and the first gate electrode 1015′″″ is isolated from the N type epitaxial layer by a first gate oxide film (GOX1) 1019′″″ along a trench sidewall and a first insulating film 1016′″″ on a bottom of the gate trench, wherein the first gate oxide film 1019′″″ has a thinner thickness than the first insulating film 1016′″″, and furthermore, the first gate electrode 1015′″″ is connected to a gate metal runner 1052′″″ through a trenched contact 1042′″″.

Please refer to FIG. 10G for another preferred embodiment of A1-A1′ cross-sectional view of FIG. 10A with a new and improved device structure. The GaN device has a similar structure to FIG. 10C, except that the present invention further comprises an n+ source region 1011′′″″ disposed on a top portion of the top epitaxial layer 1033′′″″, connecting with the gate trench 1002′′″″ and the source contact trench 1004′′″″ for on-resistance reduction, wherein the n+ source region 1011′′″″ is formed by the deposition of a heavily doped N type nitride semiconductor layer or by Si ion implantation into the top epitaxial layer 1033′′″″.

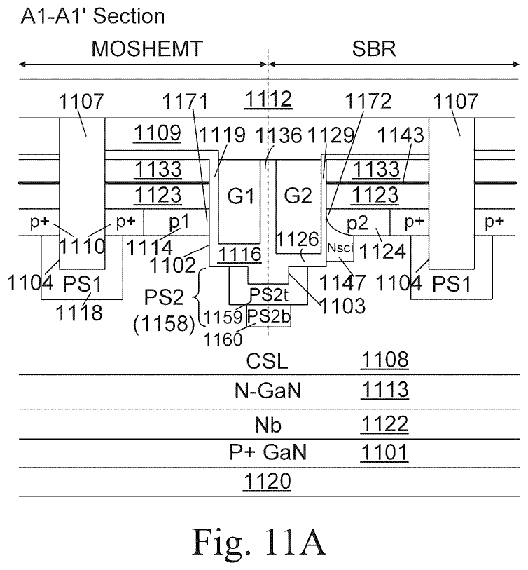

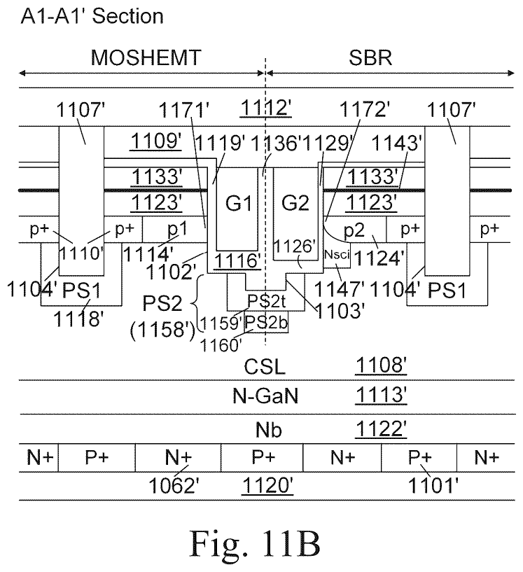

Please refer to FIG. 11A for another preferred embodiment of A1-A1′ cross-sectional view of FIG. 10A with a new and improved device structure. The GaN device has a similar structure to FIG. 10C, except for the different substrate and an additional buffer layer. In this invention, the GaN device is formed on a P+GaN substrate 1101, and an N−GaN buffer layer (Nb, as illustrated) 1122 is sandwiched between the P+GaN substrate 1101 and the bottom epitaxial layer 1113 with a resistivity Rb lower than a resistivity R of the bottom epitaxial layer 1113.

Please refer to FIG. 11B for another preferred embodiment of A1-A1′ cross-sectional view of FIG. 10A with a new and improved device structure. The GaN device has a similar structure to FIG. 11A, except that, the GaN device in FIG. 11A further comprises a plurality of heavily doped N+GaN regions 1162′ in the P+GaN substrate 1101′ to form a plurality of alternating P+ and N+ regions in the substrate.

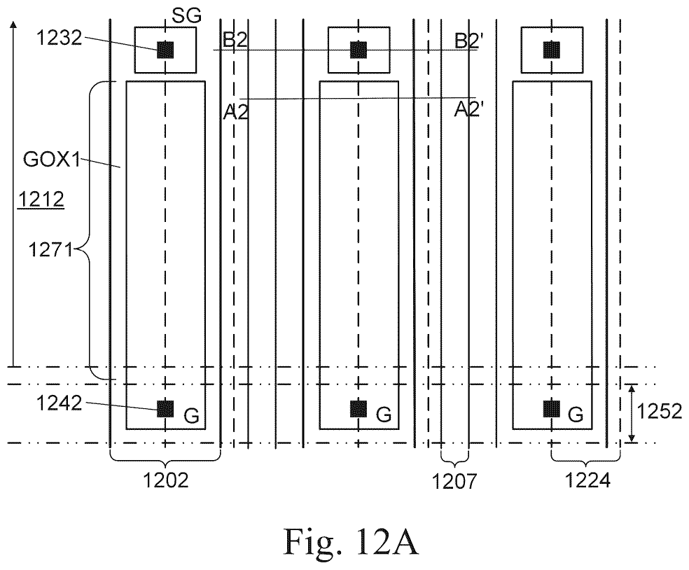

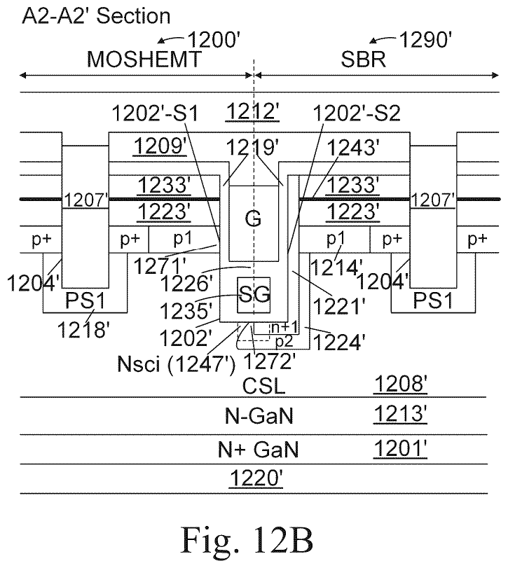

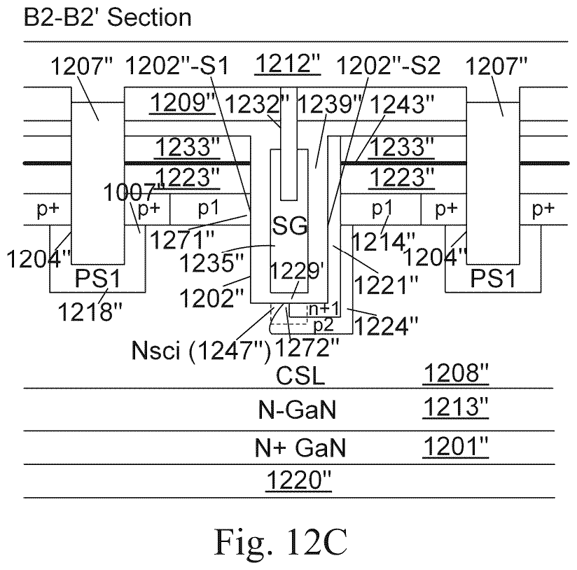

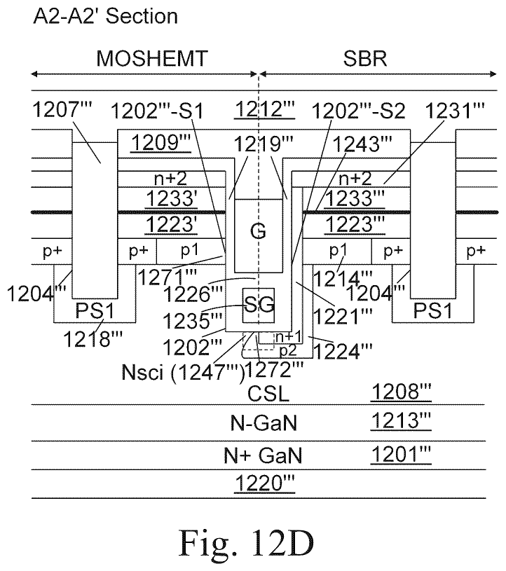

Please refer to FIG. 12A for another top view of a GaN power device having an asymmetric gate trench structure with stripe cells layout. The trenched source contacts 1207 are disposed between the adjacent gate trenches 1202, and a second p body (p2) region 1224 is grounded to a source metal 1212 through the trenched source contacts 1207. According to this invention, a MOSHEMT channel region 1271 is formed along a first trench sidewall of the gate trench 1202 with a first gate oxide GOX1 and two electrodes comprising a gate electrode and a shielded gate electrode are formed in the gate trench 1202, wherein the gate electrode as a first gate electrode is shorted to a gate metal runner 1252 through a first gate contact (G, as illustrated) 1242 and the shielded gate electrode as a second gate electrode is shorted to a source metal 1212 through a shielded gate contact (SG, as illustrated) 1232.

Please refer to FIG. 12B for a preferred embodiment of A2-A2′ cross-sectional view of FIG. 12A with a new and improved device structure. The GaN device has a similar structure to FIG. 4, except that the GaN SBR 1290′ in the present invention further comprises a short channel implant (Nsci, as illustrated) region 1247′ formed along a portion of the bottom region of the gate trench 1202′ below the shielded gate electrode 1235′, a second p body (p2, as illustrated) region 1224′ and a first source (n+1, as illustrated) region 1221′ are formed surrounding a second sidewall 1202′-S2 of the gate trench 1202′ and a portion of the bottom region of the gate trench 1202′ adjacent to the second sidewall 1202′-S2, wherein the second sidewall 1202′-S2 is opposite to the first gate trench sidewall 1202′-S1. A second channel region 1272′ is formed in the p2 body region 1224′ along a bottom region of the gate trench 1202′, wherein the second channel region has a channel length shorter than that of the first channel region 1271′.

Please refer to FIG. 12C for a preferred embodiment of B2-B2′ cross-sectional view of FIG. 12A with a new and improved device structure, which is a cross-sectional view of the shielded gate electrode contact area. The GaN power device has a similar structure to FIG. 12B, except for the different gate structure in the gate trench 1202″. In the present invention, a shielded gate electrode (SG, as illustrated) 1235″ is formed in each of the gate trenches 1202″ and vertically isolated from the N type epitaxial layer by a second gate oxide film (GOX2) 1229″ on a bottom of the gate trench and laterally isolated from the epitaxial layer by a third gate oxide film (GOX3) 1239″ on the gate trench sidewall, wherein the second gate oxide film 1229″ has a thinner thickness than that of the third gate oxide film 1239″, and furthermore, the shielded gate electrode 1235″ is connected to a source metal 1212″ through a shielded gate contact 1232″.

Please refer to FIG. 12D for a preferred embodiment of A2-A2′ cross-sectional view of FIG. 12A with a new and improved device structure. The GaN device has a similar structure to FIG. 12A, except that the present invention further comprises a second n+ source (n+2, as illustrated) region 1231′″ disposed on a top portion of the top epitaxial layer 1233′″, connecting with the first source (n+1, as illustrated) region 1221′″ for on-resistance reduction, wherein the n+2 region 1231 ′″ is formed by the deposition of a heavily doped nitride semiconductor layer of a first conductivity type or by Si ion implantation into the top epitaxial layer 1231′″.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A nitride semiconductor device, comprising:
at least three epitaxial layers including a top, a middle and a bottom epitaxial layers of a first conductivity type, grown on a substrate;
said top epitaxial layer having a different band gap from that of said middle epitaxial layer of said first conductivity type;
at least one heterojunction formed at an interface between said top and middle epitaxial layers creating a two-dimensional electron gas (2DEG) thus allowing current flow thereof;
a body region of second conductivity type formed at a top portion of said bottom epitaxial layer connecting with a body contact region of said second conductivity type;
a gate trench penetrating through said top and middle epitaxial layers, and said body region, and stopping in said bottom epitaxial layer;
a source contact trench penetrating through said top and middle epitaxial layers, and said body contact regions, and stopping in said bottom epitaxial layer;
a gate electrode disposed into said gate trench, and laterally isolated from said at least three epitaxial layers with a gate oxide on sidewalls of said gate trench;
at least one pair of first P-shield (PS1) regions of said second conductivity type formed in said bottom epitaxial layer of said first conductivity type, and separated from each other in a horizontal direction by a Junction Field Effect Transistor (JFET) region of said first conductivity type with a doping concentration higher than that of said bottom epitaxial layer, wherein said each of said one pair of PS1 regions surrounding a bottom region of said source contact trench and connecting with said body contact regions; and
a contact metal plug filling into said source contact trench connecting said heterojunction and said body contact regions with a source metal.

2. The nitride semiconductor device of claim 1, wherein said gate electrode is surrounded by a first insulating film on a bottom region of said gate trench with a thickness greater than that of said gate oxide.

3. The nitride semiconductor device of claim 1, wherein said gate oxide is an atomic layer deposited (ALD) SiO₂, Al₂O₃ or HfO₂ layer padded with an Aluminum Nitride (AlN) or unintentionally doped (UID) GaN interlayer on said sidewalls of said gate trench for channel mobility enhancement.

4. The nitride semiconductor device of claim 1, wherein said top/middle epitaxial layers are either GaN/Al_{X}Ga_{Y}N layers or Al_{X}Ga_{Y}N/GaN layers, wherein X=1 and Y=1, or 0<X<1 and Y=1−X.

5. The nitride semiconductor device of claim1, comprising three epitaxial layers of Al_{X}Ga_{Y}N/GaN/Al_{X}Ga_{Y}N on top of said body region, and two heterojunctions formed at the two interfaces of Al_{X}Ga_{Y}N/GaN/Al_{X}Ga_{Y}N epitaxial layers above said body region, wherein X=1 and Y=1, or 0<X<1 and Y=1−X.

6. The nitride semiconductor device of claim 1, further comprising a source region of said first conductivity type disposed on a top portion of said top epitaxial layer, connecting with said gate trench and said contact metal plug for more on-resistance reduction, wherein said source region is formed by deposition of a heavily doped nitride semiconductor layer of said first conductivity type or by Si ion implantation into said top epitaxial layer.

7. The nitride semiconductor device of claim 1, wherein said at least one pair of PS1 regions comprising a pair of top PS1 (PS1t) regions separated by a first top JFET (JFET1t) region, and a pair of bottom PS1 (PS1b) regions separated by a first bottom JFET (JFET1b) region; wherein each of said PS1t regions surrounds said bottom region of said source contact trench while said PS1b regions are below said PS1t regions; said PS1b region having a doping concentration D_{PS1b} higher than a doping concentration D_{PS1t} of said PS1t; said JFET1b having a doping concentration D_{JFET1b} higher than a doping concentration D_{JFET1t} of said JFET1t region; and said JFET1b region having a width W_{J1b} narrower than a width W_{J1t} of said JFET1t region.

8. The nitride semiconductor device of claim 1, further comprising a shielded gate electrode disposed below said gate electrode in said gate trench.

9. The nitride semiconductor device of claim 1, further comprising a super junction (SJ) structure having a P column (PC) region of said second conductivity type disposed on a buffer layer of said first conductivity type with a resistivity Rb sandwiched between said substrate and said bottom epitaxial layer, and said PC region is connected to said body contact region.

10. The nitride semiconductor device of claim 9, wherein said substrate has said first conductivity type and said epitaxial layer comprises a single epitaxial layer having a uniform doping concentration with a resistivity R, wherein said R<said Rb.

11. The nitride semiconductor device of claim 10, further comprising at least two sidewall P-shield (SPS) regions of said second conductivity type facing each other with a doping concentration higher than a doping concentration of said PC region, adjoining said PC region and being spaced apart from said body region, and a Junction Field Effect Transistor (JFET) region of said first conductivity type formed between said two SPS regions with a doping concentration higher than that of said epitaxial layer.

12. The nitride semiconductor device of claim 1, further comprising a buffer layer of said first conductivity with a resistivity Rb disposed between said bottom epitaxial layer and said substrate, wherein said bottom epitaxial layer having a resistivity R, and said R>said Rb; said substrate having a second conductivity type or comprising a plurality of heavily doped regions of said first conductivity type and heavily doped regions of said second conductivity type to form a plurality of alternating P+ and N+ regions in said substrate.

13. The nitride semiconductor device of claim 1, further comprising a L-shape P-shield (LPS) region of said second conductivity type disposed beneath said gate trench, and aside a sidewall of said gate trench and adjoining a lower surface of said body region.

14. The nitride semiconductor device in claim 1, wherein said gate trench has a at least one step-trench (ST) structure with a first type gate trench above a second type gate trench; said first type gate trench has a trench width wider than that of said second type gate trench; said first gate electrode disposed in said first type gate trench surrounded with a first insulating film on a bottom region of said first type gate trench, and with said gate oxide on sidewalls of said first type gate trench, wherein said first insulating film has a thickness greater than said gate oxide; and
a second P-shield (PS2) region of said second conductivity type surrounding a bottom and sidewalls of said second type gate trench filled up with said first insulating film;
said PS2 region comprising at least two sub-PS2 regions including a top PS2t region and a bottom PS2b region, wherein said bottom PS2b region is below said second top PS2t region with a doping concentration lower than that of said second top PS2t region; and
at least one grounded P (GP) region of said second conductivity type surrounding a sidewall of said first type gate trench connecting with said body region and said PS2 region.

15. An integrated circuit comprising:
a GaN MOSHEMT and a GaN SBR integrated in each unit cell;
at least three epitaxial layers including a top, a middle and a bottom epitaxial layers of a first conductivity type, grown on a substrate;
said top epitaxial layer of said first conductivity type having a different band gap from that of said middle epitaxial layer of said first conductivity type;
at least one heterojunction formed at an interface between said top and said middle epitaxial layers creating a two-dimensional electron gas (2DEG) thus allowing current flow thereof;
a first body region of said GaN MOSHEMT and a second body region of said GaN SBR of said second conductivity type formed at a top portion of said bottom epitaxial layer;
a gate trench penetrating through said top and middle epitaxial layers, and said first and second body regions, and stopping in said bottom epitaxial layer;
a source contact trench penetrating through said top and middle epitaxial layers, and body contact regions of said second conductivity type, and stopping in said bottom epitaxial layer;
a contact metal plug filling into said source contact trench connecting said heterojunction and body contact regions with a source metal.
said GaN MOSHEMT further comprising:
a first gate electrode disposed into said gate trench, and laterally isolated from said at least three epitaxial layers with a first gate oxide on a first sidewall of said gate trench;
said first gate electrode surrounded with a first insulating film on a bottom of said gate trench and said first insulating film having a thickness greater than that of said first gate oxide;
a first channel region formed in said first body region along said first sidewall of said gate trench;
said GaN SBR further comprising:
a second gate electrode disposed in said gate trench side by side with said first gate electrode, and isolated from said first gate electrode with an inter-polysilicon oxide (IPO);
said second gate electrode laterally isolated from said at least three epitaxial layers with a second gate oxide on a second sidewall of said gate trench having an oxide thickness less than that of said first gate oxide;
said second gate electrode surrounded with a second insulating film on a bottom region of said gate trench and said second insulating film having a thickness greater than that of said second gate oxide; and said first insulating film having a thickness greater than that of said second insulating film;
a second channel region formed in said second body region along said second sidewall of said gate trench opposite to said first sidewall, wherein said second channel region has a channel length shorter than that of said first channel region;
a short channel implant (SCI) region of said first conductivity type formed along said second sidewall and surrounding said second gate electrode;
said second gate electrode shorted to said source metal through a gate contact of said GaN SBR;
a current spreading layer (CSL) of said first conductivity type formed at a top portion of said bottom epitaxial layer below said first and second body regions with a doping concentration higher than that of said bottom epitaxial layer; and
a first P-shield (PS1) region of said second conductivity type surrounding a bottom region of said source contact trench and connecting with said body contact regions.

16. The integrated circuit of claim 15, wherein said gate trench has at least a one-step trench (ST) structure with a first type gate trench above a second type gate trench; said first type gate trench has a trench width wider than that of said second type gate trench; said first gate electrode disposed in said first type gate trench surrounded with said first insulating film on a bottom of said first type gate trench, and with said first gate oxide on said first gate trench sidewall of said first type gate trench; said second gate electrode disposed in said first gate trench surrounded with said second insulating film on a bottom region of said first type gate trench, and with said second gate oxide on said second gate trench sidewall of said first type gate trench; and
a second P-shield (PS2) region of said second conductivity type surrounding a bottom and sidewalls of said second type stripe gate trench filled up with said first insulating film;
said PS2 region comprising at least two sub-PS2 regions including a top PS2t region and a bottom PS2b region, wherein said bottom PS2b region is below said top PS2t region with a doping concentration lower than that of said top PS2t region; and
at least one grounded P (GP) region of said second conductivity type surrounding a portion of sidewalls of said first type gate trench connecting with said second body region and said PS2 region.

17. The integrated circuit of claim 15, further comprising a first source region of said first conductivity type disposed on a top portion of said top epitaxial layer, connecting with said gate trench and said source contact trench for more on-resistance reduction, wherein said first source region is formed by the deposition of a heavily doped nitride semiconductor layer of said first conductivity type or Si ion implantation into said top epitaxial layer.

18. The integrated circuit of claim 16, further comprising a buffer layer of said first conductivity with a resistivity Rb disposed between said bottom epitaxial layer and said substrate, wherein said bottom epitaxial layer having a resistivity R, and said R>said Rb; said substrate having a second conductivity type or comprising a plurality of heavily doped regions of said first conductivity type and heavily doped region of second conductivity type to form a plurality of alternating P+ and N+ regions in said substrate.

19. An integrated circuit comprising:
a GaN MOSHEMT and a GaN SBR disposed in a gate trench of each unit cell;
at least three epitaxial layers including a top, a middle and a bottom epitaxial layers of a first conductivity type, grown on a substrate;
said top epitaxial layer of said first conductivity type having a different band gap from that of said middle epitaxial layer of said first conductivity type;
at least one heterojunction formed at an interface between said top and said middle epitaxial layers creating a two-dimensional electron gas (2DEG) thus allowing current flow thereof;
a first body region of said GaN MOSHEMT of a second conductivity type formed at a top portion of said bottom epitaxial layer;
a gate trench penetrating through said top and middle epitaxial layers, and said first body region, and stopping in said bottom epitaxial layer;
a source contact trench penetrating through said top and middle epitaxial layers, and body contact regions, and stopped in said bottom epitaxial layer;
a contact metal plug filling into said source contact trench connecting said heterojunction, and said body contact regions of said second conductivity type with a source metal.
a current spreading layer (CSL) region of said first conductivity type formed at a top portion of said bottom epitaxial layer below said first and second body regions with a doping concentration higher than that of said bottom epitaxial layer;
a first P-shield (PS1) region of said second conductivity type surrounding bottoms of said source contact trench;
a gate electrode disposed in an upper portion of said gate trench, and a shielded gate electrode disposed below said gate electrode and isolated from said gate electrode by an inter-poly oxide (IPO) layer;
said gate electrode acting as a first gate electrode laterally isolated from said epitaxial layer by a first gate oxide of said GaN MOSHEMT on first sidewall of said gate trench, and said shielded gate electrode acting as a second gate electrode vertically isolated from said epitaxial layer by a second gate oxide of said GaN SBR on said bottom region of said gate trench, wherein said second gate oxide has a thickness less than that of said first gate oxide;
said GaN MOSHEMT further comprising:
a first channel region of said GaN MOSHEMT formed in said first body region along said first sidewall of said gate trench;
said GaN SBR further comprising:
a second body region and a first source region surrounding a second sidewall of said gate trench, and a portion of said bottom region of said gate trench adjacent to said second sidewall, wherein said second sidewall is opposite to said first gate trench sidewall;
a second channel region formed in a second body region along said bottom region of said gate trench, wherein said second channel region has a channel length shorter than that of said first channel region; and
said second gate electrode shorted to said source metal through a shielded gate contact of said GaN SBR.

20. The integrated circuit of claim 19, further comprising a second source region of said first conductivity type disposed on a top portion of said top epitaxial layer, connecting with said first source region for on-resistance reduction, wherein said second source region is formed by the deposition of a heavily doped nitride semiconductor layer of said first conductivity type or by Si ion implantation into said top epitaxial layer.
